(19) United States
(12) Patent Application Publication
(10) Pub. No.: US 2025/0379156 A1
(43) Pub. Date: Dec. 11, 2025

(54) SEMICONDUCTOR WAFER AND METHOD OF MANUFACTURING SEMICONDUCTOR WAFER

(71) Applicant: Mitsubishi Electric Corporation, Tokyo (JP)

(72) Inventors: Shingo SONODA, Tokyo (JP); Gensei NISHI, Tokyo (JP); Takuya FUJIWARA, Tokyo (JP)

(73) Assignee: Mitsubishi Electric Corporation, Tokyo (JP)

(21) Appl. No.: 19/069,191

(22) Filed: Mar. 3, 2025

(30) Foreign Application Priority Data
Jun. 11, 2024 (JP) 2024-094254

(51) Int. Cl. H01L 23/544

(52) U.S. Cl. CPC H01L 23/544; H01L 2223/54426; H01L 2223/54493

(57) ABSTRACT

A semiconductor wafer capable of accurately detecting a position of a notch part is provided. A semiconductor wafer in which a semiconductor chip is formed includes: a notch part provided to an edge part of the semiconductor wafer; and a light shielding part provided to the edge part of a surface parallel to a surface in which the semiconductor chip is formed in surfaces included in the semiconductor wafer to sandwich an outer surrounding of the notch part or the notch part and having light transmissivity different from the semiconductor wafer. Accordingly, the position of the notch part can be accurately detected.

### BACKGROUND

### Technical Field

The present disclosure relates to a semiconductor wafer and a method of manufacturing the semiconductor wafer.

### Description of the Background Art

Disclosed in a conventional technique is a semiconductor wafer in which a dot mark is formed in a planar surface part of a chamfered part of a V notch (for example, Japanese Patent Application Laid-Open No. 2002-93692).

In the conventional technique, a chamfered part provided to an edge of a semiconductor wafer is irradiated with laser light outputted from a line sensor to detect a position of a notch part provided to the semiconductor wafer.

### SUMMARY

However, there is a problem that when an edge part of the semiconductor wafer is trimmed and a chamfered width decreases or when the semiconductor wafer is warped, for example, an area of a chamfered part in a direction perpendicular to light emitted from a line sensor projector provided to the semiconductor wafer to detect the notch part decreases and a position of the notch part cannot be accurately detected.

An object of the present disclosure is to provide a semiconductor wafer capable of accurately detecting a position of a notch part.

A semiconductor wafer according to the present disclosure is at least one semiconductor wafer in which a semiconductor chip is formed. The semiconductor wafer according to the present disclosure includes a notch part and a light shielding part. The notch part is provided to an edge part of the semiconductor wafer. The light shielding part is provided to the edge part of a surface parallel to a surface in which the semiconductor chip is formed in surfaces included in the semiconductor wafer to sandwich an outer surrounding of the notch part or the notch part, and has light transmissivity different from the surface in which the semiconductor chip is formed.

According to the semiconductor wafer according to the present disclosure, a position of a notch part can be accurately detected.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a top view of a semiconductor wafer according to an embodiment 1 in the present disclosure.

FIG. 2 is an enlarged view around a notch part of the semiconductor wafer according to the embodiment 1 in the present disclosure.

FIG. 3 is a top view of the semiconductor wafer according to the embodiment 1 in the present disclosure.

FIG. 4 is an enlarged view around the notch part of the semiconductor wafer according to the embodiment 1 in the present disclosure.

FIG. 5 is a top view of the semiconductor wafer according to the embodiment 1 in the present disclosure.

FIG. 6 is a diagram illustrating a method of manufacturing the semiconductor wafer according to the embodiment 1 in the present disclosure.

FIG. 7 is a diagram illustrating a method of detecting the notch part of the semiconductor wafer according to the embodiment 1 in the present disclosure.

FIG. 8 is a diagram schematically illustrating a detection result in a line sensor light receiver according to the embodiment 1 in the present disclosure.

FIG. 9 is a top view of a semiconductor wafer according to an embodiment 2 in the present disclosure.

FIG. 10 is an enlarged view around a notch part of the semiconductor wafer according to the embodiment 2 in the present disclosure.

FIG. 11 is a cross-sectional view of a semiconductor wafer according to an embodiment 3 in the present disclosure.

FIG. 12 is a cross-sectional view of the semiconductor wafer according to the embodiment 3 in the present disclosure.

FIG. 13 is a cross-sectional view of the semiconductor wafer according to the embodiment 3 in the present disclosure.

FIG. 14 is a cross-sectional view of the semiconductor wafer according to the embodiment 3 in the present disclosure.

FIG. 15 is a top view of a semiconductor wafer according to an embodiment 4 in the present disclosure.

FIG. 16 is a diagram illustrating a method of manufacturing the semiconductor wafer according to the embodiment 4 in the present disclosure.

FIG. 17 is a top view of the semiconductor wafer according to the embodiment 4 in the present disclosure.

FIG. 18 is a diagram illustrating a method of manufacturing the semiconductor wafer according to the embodiment 4 in the present disclosure.

FIG. 19 is a diagram illustrating a method of manufacturing a semiconductor wafer according to an embodiment 5 in the present disclosure.

FIG. 20 is a diagram illustrating a method of manufacturing the semiconductor wafer according to the embodiment 5 in the present disclosure.

FIG. 21 is a diagram illustrating a method of manufacturing the semiconductor wafer according to the embodiment 5 in the present disclosure.

FIG. 22 is a diagram illustrating a method of manufacturing the semiconductor wafer according to the embodiment 5 in the present disclosure.

### DESCRIPTION OF THE PREFERRED EMBODIMENTS

Embodiments of the present disclosure are described with reference to the appended diagrams hereinafter. Since the diagrams are schematically illustrated, a mutual relationship of sizes and positions respectively illustrated in the different diagrams is not necessarily limited thereto, but may be appropriately changed. In the description hereinafter, the same reference numerals will be assigned to the similar constituent elements, and the constituent elements having the same reference numeral have the similar name and function. Accordingly, the detailed description on them may be omitted in some cases.

### Embodiment 1

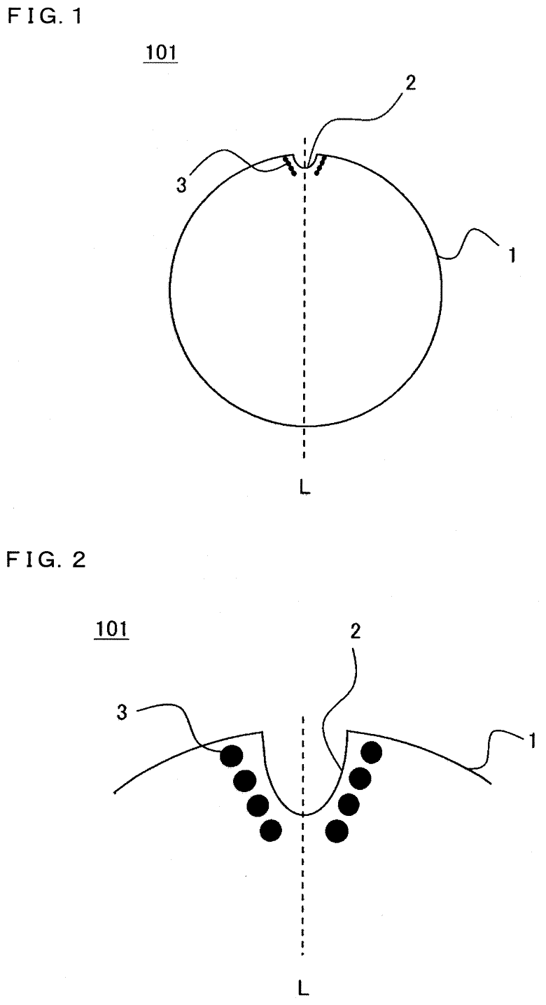

A semiconductor wafer 101 according to an embodiment 1 is described using FIGS. 1 to 8. FIG. 1 is a top view of the semiconductor wafer 101 according to the embodiment 1. As illustrated in FIG. 1, the semiconductor wafer 101 according to the present embodiment includes an edge part 1, a notch part 2, and a light shielding part 3.

A semiconductor chip is formed in an upper surface of the semiconductor wafer 101. A side on which the semiconductor chip is provided is the upper surface based on the semiconductor wafer 101. FIG. 1 illustrates the upper surface of the semiconductor wafer 101. A surface different from the upper surface, that is to say, a surface on a side opposite to the upper surface is a lower surface. A direction passing through the upper surface and the lower surface is a thickness direction. A surface other than the upper surface and the lower surface is a side surface. The same applies to the description hereinafter.

The semiconductor wafer 101 is formed of silicon carbide SiC, for example. The semiconductor wafer 101 is transparent or semitransparent, for example. That is to say, light passes through the semiconductor wafer 101, for example.

The edge part 1 is an outer surrounding part of the semiconductor wafer 101. A chamfered part is provided to the edge part 1. The chamfered part is provided as a surface having an angle with respect to the upper surface of the semiconductor wafer 101. The chamfered part is provided to the edge part 1 around a whole periphery of the semiconductor wafer 101, for example.

The notch part 2 is a notch provided to the edge part 1 of the semiconductor wafer 101. The notch part 2 is used as a reference for positioning the semiconductor wafer 101, for example. When the notch part 2 is detected, the semiconductor wafer 101 can be disposed in a desired position, and the semiconductor chip can be formed in the upper surface of the semiconductor wafer 101. The notch part 2 is used as a landmark for aligning positions of the plurality of semiconductor wafers 101.

The notch part 2 has a shape in which arcs are combined as illustrated in FIG. 1, for example. The notch part 2 may have a shape in which curved lines are combined. The notch part 2 may have a shape in which straight lines are combined such as a V-like shape. The notch part 2 may have a shape in which a straight line and a curved line are combined. As illustrated in FIG. 1, the notch part 2 has a shape symmetric with respect to a center line L passing a center the semiconductor wafer 101. The notch part 2 may not have a shape symmetric with respect to the center line L.

FIG. 2 is an enlarged view around the notch part 2 of the semiconductor wafer 101 according to the embodiment 1. The light shielding part 3 is a part having light transmissivity different from the semiconductor wafer 101. When the semiconductor wafer 101 is transparent, the light shielding part 3 is provided as a part having lower light transmissivity than the other part of the semiconductor wafer 101, for example. When the light shielding part 3 is provided, a detection apparatus detecting the notch part 2 can determine that a region, through which a large amount of light passes, between regions through which a small amount of light passes is the notch part 2, and detect the position of the notch part 2.

The light shielding part 3 is provided near the notch part 2. The light shielding part 3 is provided to a position in proximity to the notch part 2. The light shielding part 3 is provided to a surface parallel to a surface in which the semiconductor chip is formed in surfaces included in the semiconductor wafer 101. That is to say, the light shielding part 3 is provided to a surface parallel to the upper surface of the semiconductor wafer 101.

The light shielding part 3 is provided to the surface parallel to the surface in which the semiconductor chip is formed; thus, even when a width of the chamfered part in a direction perpendicular to light emitted from a projector detecting the notch part 2 gets small in a case where the semiconductor wafer 101 is warped or deformed or the edge part 1 of the semiconductor wafer 101 is trimmed, for example, the light shielding part 3 can sufficiently shield light, and the position of the notch part 2 can be accurately detected. That is to say, since the light shielding part 3 is provided to the surface parallel to the surface in which the semiconductor chip is formed, the position of the notch part 2 can be accurately detected without influence of warpage and deformation of the semiconductor wafer 101.

The light shielding part 3 is provided to an outer surrounding of the notch part 2. The light shielding part 3 is provided to surround the notch part 2. The light shielding part 3 needs not cover the outer surrounding of the notch part 2 with no gap, but may intermittently surround the notch part 2 as illustrated in FIG. 1, for example.

The light shielding part 3 is provided to the upper surface of the semiconductor wafer 101, for example. The light shielding part 3 is provided onto a surface in which the semiconductor chip is formed in the semiconductor wafer 101. The light shielding part 3 is provided to a part of the upper surface of the semiconductor wafer 101 in which the semiconductor chip is not formed.

The light shielding part 3 is a dot mark as illustrated in FIG. 2, for example. The light shielding part 3 is formed of a plurality of dot marks. The plurality of dot marks are disposed to the outer surrounding of the notch part 2 to surround the notch part 2. The plurality of dot marks are disposed to be symmetric with respect to the center line L, for example. It is sufficient that the plurality of dot marks are arranged from the edge part 1 of the semiconductor wafer 101 toward the center of the semiconductor wafer 101, for example. The plurality of dot marks may not be disposed to be symmetric with respect to the center line L; however, it is sufficient that the plurality of dot marks are provided to positions so that the position of the notch part 2 can be detected.

The light shielding part 3 preferably has larger resolution than a line sensor light receiver receiving light emitted from a line sensor projector described hereinafter. The resolution of the line sensor light receiver is approximately 30 mm, for example. The dot mark is a circle having a diameter of several micrometers to several tens of micrometers, for example. The dot mark has a diameter of approximately 100 μm at maximum, for example. The plurality of dot marks are disposed to be arranged side by side so as to have larger resolution as the whole light shielding part 3 than the line sensor light receiver. When a beam width of laser light emitted from a line sensor projector 14 is several tens of millimeters, the light shielding part 3 is disposed so that the beam width of several tens of millimeters includes the edge part 1 the semiconductor wafer 101 and the light shielding part 3.

The light shielding part 3 may not be formed into the circular shape. The light shielding part 3 may have a polygonal shape such as a triangle or a tetragon, a continuous linear shape, a shape surrounded by a curved line, or a shape in which a curved line and a straight line are combined.

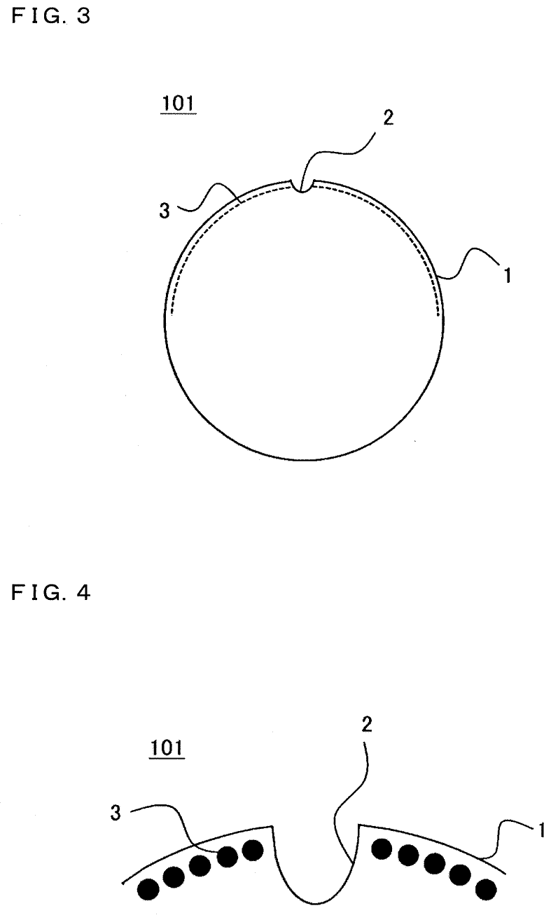

FIG. 3 is a top view of the semiconductor wafer 101 according to the embodiment 1. FIG. 4 is an enlarged view around the notch part 2 of the semiconductor wafer 101 according to the embodiment 1. The light shielding part 3 may be provided to the edge part 1 as illustrated in FIG. 3 and FIG. 4. The light shielding part 3 is provided near the notch part 2 in the edge part 1. The light shielding part 3 is arranged along a shape of the semiconductor wafer 101, and is provided to the edge part 1, for example. The light shielding part 3 is provided to sandwich the notch part 2. The light shielding part 3 may be provided to only half the periphery of the edge part 1 including the notch part 2.

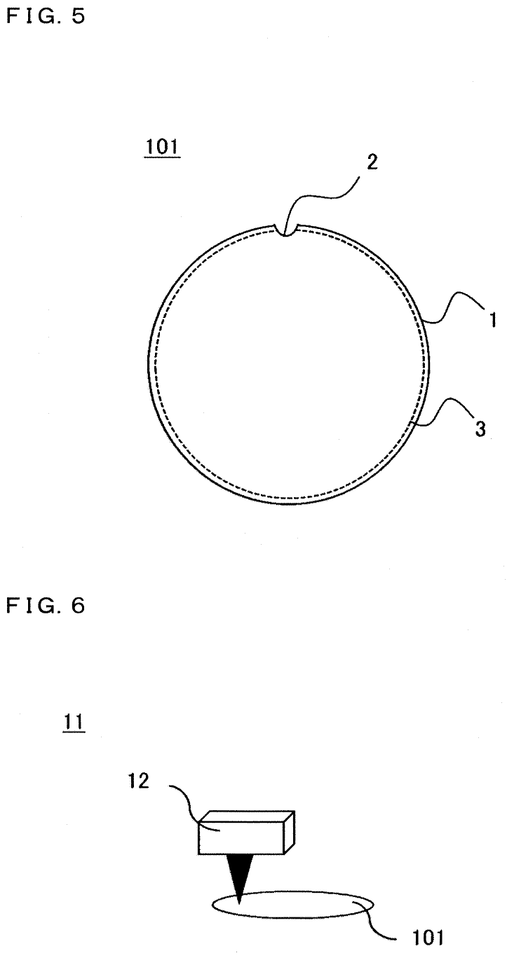

FIG. 5 is a top view of the semiconductor wafer 101 according to the embodiment 1. The light shielding part 3 may be provided to the whole periphery of the edge part 1 of the semiconductor wafer 101 as illustrated in FIG. 5. Also in a case illustrated in FIG. 5, the light shielding part 3 is provided to the edge part 1 to sandwich the notch part 2.

The semiconductor wafer 101 according to the present embodiment includes the notch part 2 provided to the edge part 1 of the semiconductor wafer 101 and the light shielding part 3 provided to the edge part 1 of the surface parallel to the surface in which the semiconductor chip is formed in the surfaces included in the semiconductor wafer 101 to sandwich the outer surrounding of the notch part 2 or the notch part 2 and having the light transmissivity different from the semiconductor wafer 101. Accordingly, the position of the notch part can be accurately detected.

The light shielding part 3 may be provided to a lower surface of the semiconductor wafer 101 as a surface on a side opposite to the surface in which the semiconductor chip is formed.

A method of manufacturing the semiconductor wafer 101 is described next. The method of manufacturing the semiconductor wafer 101 includes a process of forming the light shielding part 3 in the edge part 1 of the surface parallel to the surface in which the semiconductor chip is formed in the surfaces included in the semiconductor wafer 101 to sandwich the outer surrounding of the notch part 2 provided to the edge part 1 of the semiconductor wafer 101 or the notch part 2 and having the light transmissivity different from the semiconductor wafer 101.

FIG. 6 is a diagram illustrating the method of manufacturing the semiconductor wafer 101. A case of providing the light shielding part 3 by a laser mark apparatus 11 is particularly described using FIG. 6. The laser mark apparatus 11 can supply the light shielding part 3 to the upper surface or the lower surface of the semiconductor wafer 101. The light shielding part 3 supplied to the semiconductor wafer 101 is a dot mark, for example.

Galvano-scanning system, for example, can be used when the light shielding part 3 is provided. Laser light emitted from a laser oscillator is scanned by two mirrors perpendicular to each other, passes through a collecting lens, is collected to have high energy, and is emitted from a printer 12 to the semiconductor wafer 101 as a target.

When Galvano-scanning system is used, the laser mark apparatus 11 can supply a mark with a size of several micrometers to several tens of micrometers to an optional position of the semiconductor wafer 101. Laser light emitted to the semiconductor wafer 101 tarnishes or trims the upper surface of the semiconductor wafer 101 to form the light shielding part 3. The light shielding part 3 may be provided to the upper surface or the lower surface of the semiconductor wafer 101.

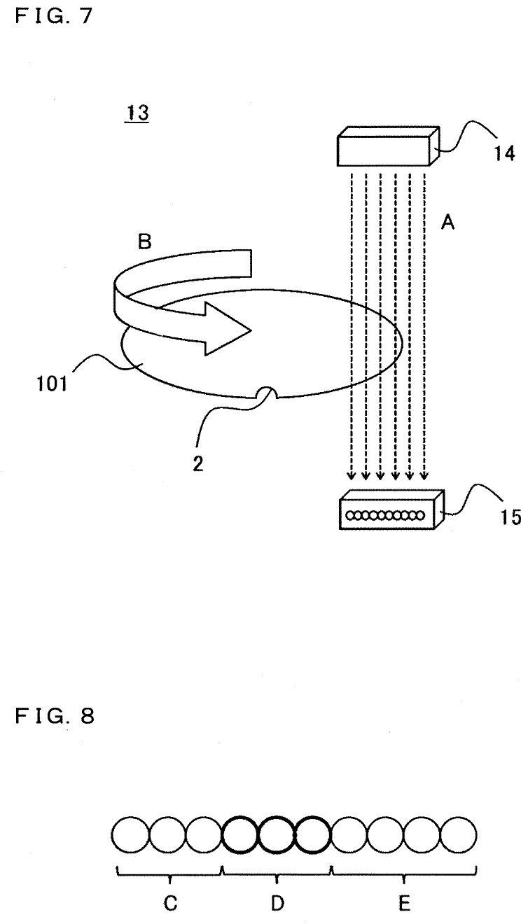

FIG. 7 is a diagram illustrating a method of detecting the notch part 2 of the semiconductor wafer 101. A notch detection unit 13 detects the position of the notch part 2 of the semiconductor wafer 101. The notch detection unit 13 includes the line sensor projector 14 and a line sensor light receiver 15.

The line sensor projector 14 and the line sensor light receiver 15 are disposed to sandwich the semiconductor wafer 101. The line sensor projector 14 is provided to face the upper surface of the semiconductor wafer 101, for example. The line sensor light receiver 15 is provided to face the lower surface of the semiconductor wafer 101, for example.

The line sensor projector 14 emits laser light. FIG. 7 schematically illustrates the laser light with an arrow A. The line sensor projector 14 emits the laser light to the semiconductor wafer 101 with a constant width. The line sensor projector 14 emits the laser light to the notch part 2 and the light shielding part 3. The width of the laser light, that is to say, a size of the laser light in a radial direction of the semiconductor wafer 101 is several tens of millimeters, for example. The line sensor projector 14 emits the laser light near the edge part 1 of the semiconductor wafer 101.

The line sensor light receiver 15 detects the laser light emitted from the line sensor projector 14. The notch detection unit 13 detects the position of the notch part 2 of the semiconductor wafer 101 from a result that the line sensor light receiver 15 detects the laser light emitted from the line sensor projector 14.

The semiconductor wafer 101 is rotated in a circumferential direction of the semiconductor wafer 101 around the center of the semiconductor wafer 101 as a center of rotation. The semiconductor wafer 101 is rotated in a direction of an arrow B illustrated in FIG. 7, for example. The line sensor projector 14 emits the laser light to the rotated semiconductor wafer 101. That is to say, the notch detection unit 13 emits the laser light to the semiconductor wafer 101 while rotating the semiconductor wafer 101.

FIG. 8 is a diagram schematically illustrating a detection result in the line sensor light receiver 15. A circle illustrated in FIG. 8 schematically illustrates a detection region for each resolution of the line sensor light receiver 15. C to E illustrated in FIG. 8 show regions in which the line sensor light receiver 15 detects the laser light. The regions C to E are regions having larger resolution than the line sensor light receiver 15.

The result of detection in the line sensor light receiver 15 is different between a case where the notch part 2 is located between the line sensor projector 14 and the line sensor light receiver 15 and a case where the light shielding part 3 is located between the line sensor projector 14 and the line sensor light receiver 15.

Described is the detection result of the line sensor light receiver 15 in the case where the light shielding part 3 is located between the line sensor projector 14 and the line sensor light receiver 15. The region D is a region facing a position where the light shielding part 3 is provided. In the case where the light shielding part 3 is located between the line sensor projector 14 and the line sensor light receiver 15, the laser light is shielded by the light shielding part 3, and the laser light does not reach the region D or an amount of the laser light reaching the region D is smaller than that reaching the region C and the region E.

The region C is a region facing a position where the light shielding part 3 of the semiconductor wafer 101 is not provided. When the semiconductor wafer 101 is transparent, the laser light emitted from the line sensor projector 14 passes through the semiconductor wafer 101 to reach the line sensor light receiver 15 without being shielded by the semiconductor wafer 101. When the semiconductor wafer 101 is semitransparent, the laser light emitted from the line sensor projector 14 passes through the semiconductor wafer 101 to reach the line sensor light receiver 15 almost without being shielded by the semiconductor wafer 101.

The region E is a region facing a position where the semiconductor wafer 101 is not provided. The laser light emitted from the line sensor projector 14 does not pass through the semiconductor wafer 101, thus reaches the line sensor light receiver 15 without being shielded by the semiconductor wafer 101.

In the meanwhile, when the notch part is located between the line sensor projector 14 and the line sensor light receiver 15, the laser light emitted from the line sensor projector 14 does not pass through the semiconductor wafer 101 also in the region D, thus reaches the line sensor light receiver 15 without being shielded by the semiconductor wafer 101. The notch detection unit 13 specifies and detects the position of the notch part 2 from a difference of the amount of laser light detected by the line sensor light receiver 15 between the regions.

As illustrated in FIG. 5, when the light shielding part 3 is provided to the semiconductor wafer 101 over the whole periphery of the edge part 1 other than the position where the notch part 2 is provided, it can be determined that a position where a detected amount of laser light is larger than the other position is a position where the notch part 2 is provided in the region D illustrated in FIG. 8.

When the light shielding part 3 is provided to the edge part 1 around the notch part 2 as illustrated in FIG. 3 and FIG. 4, it can be determined that a target position where an interval of increase of a detected amount of laser light is smaller than positions detected immediately before and after the target position is a position where the notch part 2 is provided in the region D illustrated in FIG. 8.

When the light shielding part 3 surrounds the outer surrounding of the notch part 2 as illustrated in FIG. 1 and FIG. 2, it can be determined that a target position where an interval of increase of a detected amount of laser light is smaller than positions detected immediately before and after the target position is a position where the notch part 2 is provided in the region D illustrated in FIG. 8.

Since the light shielding part 3 is disposed to be symmetric with respect to the center line L, the notch detection unit 13 can detect the position of the notch part 2 more easily.

The semiconductor wafer 101 according to the present embodiment includes the notch part 2 provided to the edge part 1 of the semiconductor wafer 101 and the light shielding part 3 provided to the edge part 1 of the surface parallel to the surface in which the semiconductor chip is formed in the surfaces included in the semiconductor wafer 101 to sandwich the outer surrounding of the notch part 2 or the notch part 2 and having the light transmissivity different from the semiconductor wafer 101. Accordingly, the position of the notch part 2 can be accurately detected.

The method of manufacturing the semiconductor wafer 101 according to the present embodiment includes the process of forming the light shielding part 3 in the edge part 1 of the surface parallel to the surface in which the semiconductor chip is formed in the surfaces included in the semiconductor wafer 101 to sandwich the outer surrounding of the notch part 2 provided to the edge part 1 of the semiconductor wafer 101 or the notch part 2 and having the light transmissivity different from the semiconductor wafer 101. Accordingly, the position of the notch part 2 can be accurately detected.

### Embodiment 2

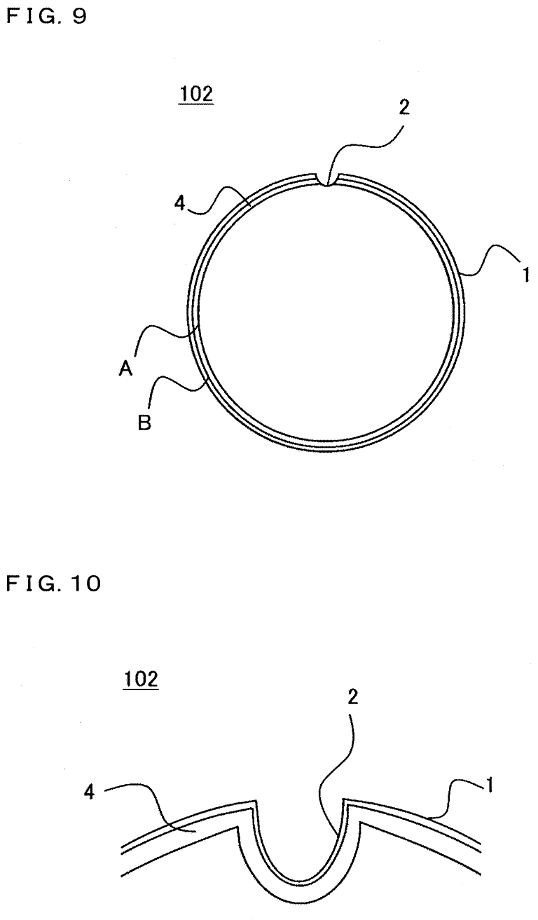

A semiconductor wafer 102 according to an embodiment 2 is described using FIG. 9 and FIG. 10. The description of a configuration similar to that in the embodiment 1 is omitted. In FIG. 9 and FIG. 10, the same reference numerals as those in FIG. 1 to FIG. 8 indicate the same or corresponding part. The semiconductor wafer 102 according to the present embodiment is different from the semiconductor wafer 101 according to the embodiment 1 in that a light shielding part 4 is a griding mark. Configurations different from those in the embodiment 1 are mainly described hereinafter.

FIG. 9 is a top view of the semiconductor wafer 102 according to the embodiment 2. FIG. 10 is an enlarged view around the notch part 2 of the semiconductor wafer 102 according to the embodiment 2. The semiconductor wafer 102 includes the light shielding part 4. The light shielding part 4 is the griding mark with unevenness. The light shielding part 4 has a rough surface state. The light shielding part 4 has the unevenness, thus has lower light transmissivity than the other part of the semiconductor wafer 102.

The light shielding part 4 is provided to a surface parallel to a surface in which the semiconductor chip is formed in surfaces included in the semiconductor wafer 102. That is to say, the light shielding part 4 is provided to a surface parallel to an upper surface of the semiconductor wafer 102. The light shielding part 4 is provided to the upper surface of the semiconductor wafer 102, for example. The light shielding part 4 is provided onto a surface in which the semiconductor chip is formed in the semiconductor wafer 102. The light shielding part 4 is provided to a part of the upper surface of the semiconductor wafer 102 in which the semiconductor chip is not formed. The light shielding part 4 may be provided to a lower surface of the semiconductor wafer 102 as a surface on a side opposite to the surface in which the semiconductor chip is formed.

The light shielding part 4 is provided to the whole periphery of the edge part 1 as illustrated in FIG. 9. As illustrated in FIG. 10, the light shielding part 4 is provided at least near the notch part 2, and is provided to the edge part 1 to sandwich the notch part 2. The light shielding part 4 may not be provided in the edge part 1 as the outer surrounding of the notch part 2. The light shielding part 4 may be provided to only half the periphery of the edge part 1 including the notch part 2. The light shielding part 4 may not be continuously formed, but may be intermittently formed.

A method of manufacturing the semiconductor wafer 102 according to the embodiment 2 is described next. Described particularly is a processing method of providing the griding mark as the light shielding part 4 to the semiconductor wafer 102. A grind stone is applied to the edge part 1 of the semiconductor wafer 102 in which the light shielding part 4 is provided to perform griding processing of griding the semiconductor wafer 102. Unevenness is formed in the upper surface of the semiconductor wafer 102 in a ground range by performing the griding processing. Since the unevenness is formed, the ground range has a rougher surface state than a range on which the griding processing is not performed. Because of the rough surface state, laser light hardly passes through the ground range.

A material having lower light transmissivity than the semiconductor wafer 102 may be applied to the semiconductor wafer 102 instead of providing the griding mark.

### Embodiment 3

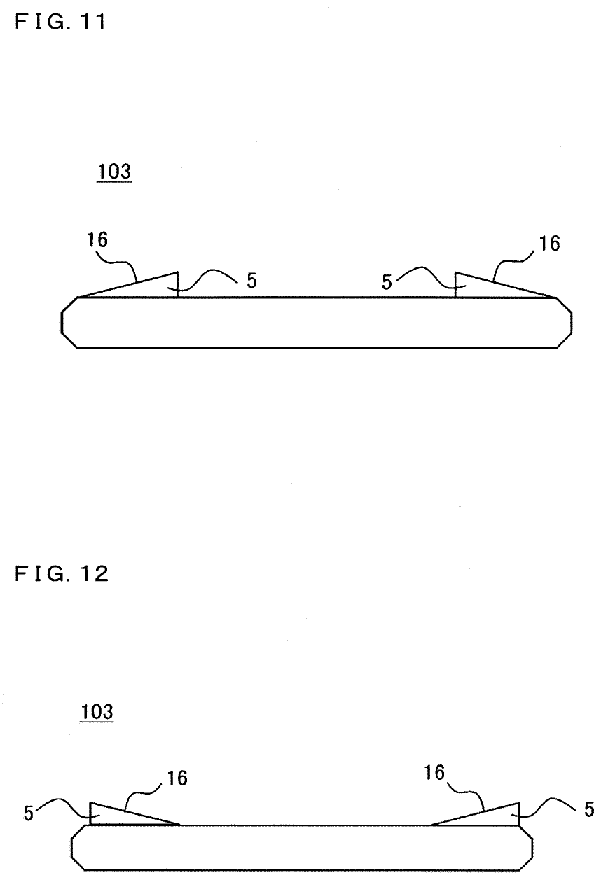

A semiconductor wafer 103 according to an embodiment 3 is described using FIG. 11 to FIG. 14. The description of a configuration similar to that in the embodiment 1 is omitted. In FIG. 11 to FIG. 14, the same reference numerals as those in FIG. 1 to FIG. 10 indicate the same or corresponding part. The semiconductor wafer 103 according to the present embodiment is different from the semiconductor wafer 101 according to the embodiment 1 in that a light shielding part 5 is a light shielding film. Configurations different from those in the embodiment 1 are mainly described hereinafter.

FIG. 11 is a cross-sectional view of the semiconductor wafer 103 according to the embodiment 3. FIG. 11 illustrates a cross section passing a center of the semiconductor wafer 103. The semiconductor wafer 103 includes the light shielding part 5. The light shielding part 5 is the light shielding film including an inclined part 16. The light shielding part 5 includes the inclined part 16, thus has lower light transmissivity than the other part of the semiconductor wafer 103. The inclined part 16 reflects laser light. Accordingly, an amount of laser light reaching the line sensor light receiver 15 is smaller in a part where the light shielding part 5 is provided than in a part where the light shielding part 5 is not provided. Thus, the notch part 2 can be detected.

The light shielding part 5 is provided to a surface parallel to a surface in which the semiconductor chip is formed in surfaces included in the semiconductor wafer 103. That is to say, the light shielding part 5 is provided to a surface parallel to an upper surface of the semiconductor wafer 103. The light shielding part 5 is provided to the upper surface of the semiconductor wafer 103, for example. The light shielding part 5 is provided onto a surface in which the semiconductor chip is formed in the semiconductor wafer 103. The light shielding part 5 is provided to a part of the upper surface of the semiconductor wafer 103 in which the semiconductor chip is not formed. The light shielding part 5 may be provided to a lower surface of the semiconductor wafer 103 as a surface on a side opposite to the surface in which the semiconductor chip is formed.

The light shielding part 5 is provided to the whole periphery of the edge part 1 in the manner similar to the embodiment 2. The light shielding part 5 is provided at least near the notch part 2, and is provided to the edge part 1 to sandwich the notch part 2. The light shielding part 5 may not be provided in the edge part 1 as the outer surrounding of the notch part 2. The light shielding part 5 may be provided to only half the periphery of the edge part 1 including the notch part 2. The light shielding part 5 may not be continuously formed, but may be intermittently formed.

The light shielding part 5 has a triangle shape in cross section as illustrated in FIG. 11, for example. The light shielding part 5 is provided so that a longest side in the cross section is directed outside in a radial direction of the semiconductor wafer 103, for example. Sides other than the longest side in the cross section are provided to have contact with the upper surface of the semiconductor wafer 103. The inclined part 16 is provided to have an angle with respect to the upper surface of the semiconductor wafer 103.

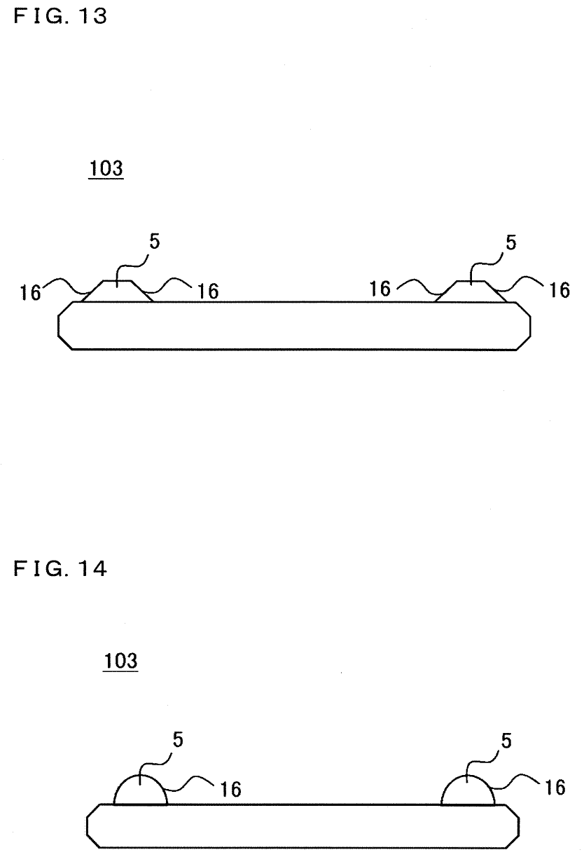

FIG. 12 is a cross-sectional view of the semiconductor wafer 103 according to the embodiment 3. FIG. 12 illustrates a cross section passing the center of the semiconductor wafer 103. It is applicable that the light shielding film as the light shielding part 5 has a triangle shape in cross section, and is provided so that a longest side in the cross section is directed inside in a radial direction of the semiconductor wafer 103 as illustrated in FIG. 12. FIG. 13 is a cross-sectional view of the semiconductor wafer 103 according to the embodiment 3. FIG. 13 illustrates a cross section passing the center of the semiconductor wafer 103. The light shielding film as the light shielding part 5 may have a trapezoidal shape in cross section as illustrated in FIG. 13. The inclined part 16 is provided to have an angle with respect to the upper surface of the semiconductor wafer 103. The plurality of inclined parts 16 are provided. One of the plurality of inclined parts 16 is directed outside in the radial direction of the semiconductor wafer 103. One of the plurality of inclined parts 16 is directed inside in the radial direction of the semiconductor wafer 103.

FIG. 14 is a cross-sectional view of the semiconductor wafer 103 according to the embodiment 3. FIG. 14 illustrates a cross section passing the center of the semiconductor wafer 103. The light shielding film as the light shielding part 5 may have a semicircular shape in cross section as illustrated in FIG. 14. The inclined part 16 is provided to have an angle with respect to the upper surface of the semiconductor wafer 103. That is to say, the inclined part 16 is not parallel to the upper surface of the semiconductor wafer 103. The cross section of the inclined part 16 is not limited to a straight shape; however, the inclined part 16 includes a curved shape as illustrated in FIG. 14. The inclined part 16 may have a planar surface or a curved surface. The inclined part 16 is provided in a direction from the lower surface of the semiconductor wafer 103 toward the upper surface thereof.

### Embodiment 4

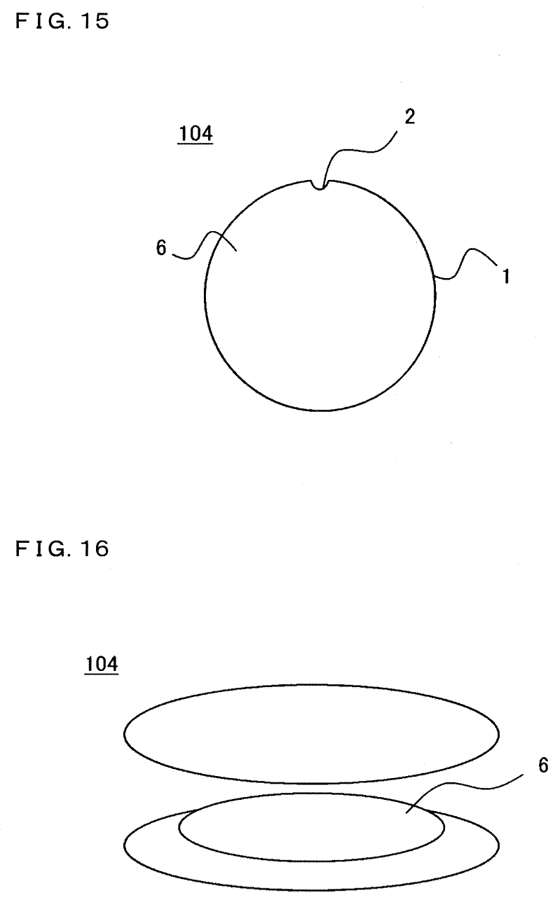

A semiconductor wafer 104 according to an embodiment 4 is described using FIG. 15 to FIG. 18. The description of a configuration similar to that in the embodiment 1 is omitted. In FIG. 15 to FIG. 18, the same reference numerals as those in FIG. 1 to FIG. 14 indicate the same or corresponding part. The semiconductor wafer 104 according to the present embodiment is different from the semiconductor wafer 101 according to the embodiment 1 in that a light shielding part 6 is an adhesive member. Configurations different from those in the embodiment 1 are mainly described hereinafter.

FIG. 15 is a top view of the semiconductor wafer 104 according to the embodiment 4. The semiconductor wafer 104 is formed by attaching two semiconductor wafers to each other. The semiconductor wafer 104 includes the light shielding part 6. The light shielding part 6 is an adhesive member having lower light transmissivity than a part of the semiconductor wafer 104 in which the light shielding part 6 is not provided. Accordingly, an amount of laser light reaching the line sensor light receiver 15 is smaller in a part where the light shielding part 6 is provided than in a part where the light shielding part 6 is not provided. Thus, the notch part 2 can be detected.

The semiconductor wafer 104 is formed by providing an adhesive member between two semiconductor wafers and attaching two semiconductor wafers to each other. The adhesive member provided between two semiconductor wafers is sandwiched between two semiconductor wafers when two semiconductor wafers are attached to each other, and spreads to a whole area between two semiconductor wafers. That is to say, the adhesive member spreads to the outer surrounding of the notch part 2. The adhesive member is provided to at least the outer surrounding of the notch part 2 of the semiconductor wafer 104. The adhesive member is provided to at least the edge part 1 to sandwich the notch part 1. Two semiconductor wafers 2 are provided to the semiconductor wafer 104. The adhesive member as the light shielding part 6 is provided between two semiconductor wafers attached to each other.

A method of manufacturing the semiconductor wafer 104 according to the present embodiment is described next. FIG. 16 is a diagram illustrating the method of manufacturing the semiconductor wafer 104 according to the embodiment 4. An adhesive member having light transmissivity different from the semiconductor wafer is disposed between two semiconductor wafers, and two semiconductor wafers are attached to each other by the adhesive member. The adhesive member is disposed near a center of the semiconductor wafer in a stage before two semiconductor wafers are attached to each other, for example. In a process of attaching two semiconductor wafers by the adhesive member, whole surfaces of two semiconductor wafers are attached to each other by the adhesive member. In a process of attaching two semiconductor wafers by the adhesive member, the adhesive member spreads to the whole surfaces of the semiconductor wafers.

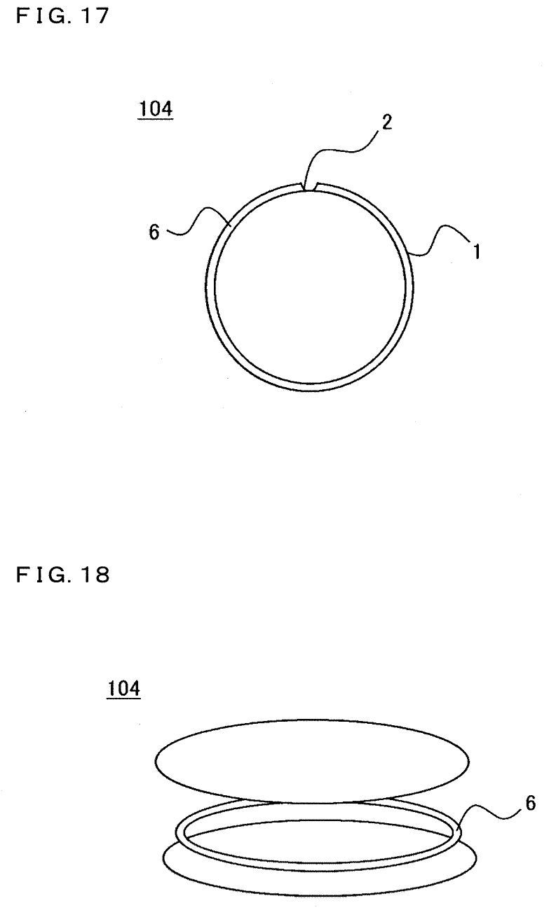

FIG. 17 is a top view of the semiconductor wafer 104 according to the embodiment 4. FIG. 17 illustrates the semiconductor wafer 104 after the semiconductor wafers are attached to each other. As illustrated in FIG. 17, the adhesive member may be applied to the edge part 1 to attach two semiconductor wafers. The adhesive member is provided to the edge part 1 to sandwich the notch part 2.

FIG. 18 is a diagram illustrating the method of manufacturing the semiconductor wafer 104 according to the embodiment 4. As illustrated in FIG. 18, the adhesive member may be provided between the edge parts 1 in two semiconductor wafers to attach two semiconductor wafers to each other.

The semiconductor wafer 104 according to the present embodiment includes the process of locating the adhesive member having light transmissivity different from the semiconductor wafer between two semiconductor wafers and attaching two semiconductor wafers to each other by the adhesive member. Thus, the semiconductor wafer 104 capable of accurately detecting the position of the notch part 2 can be obtained.

The semiconductor wafer 101, the semiconductor wafer 102, or the semiconductor wafer 103 according to the embodiment 1 to the embodiment 3 can be used for two semiconductor wafers attached to each other. The method of detecting the notch part 2 described in the embodiment 1 can be used to attach two semiconductor wafers. The method of manufacturing the semiconductor wafer 104 can include the process of detecting the notch part 2 of the semiconductor wafer and the process of locating two semiconductor wafers so that the detected notch parts 2 are overlapped with each other.

### Embodiment 5

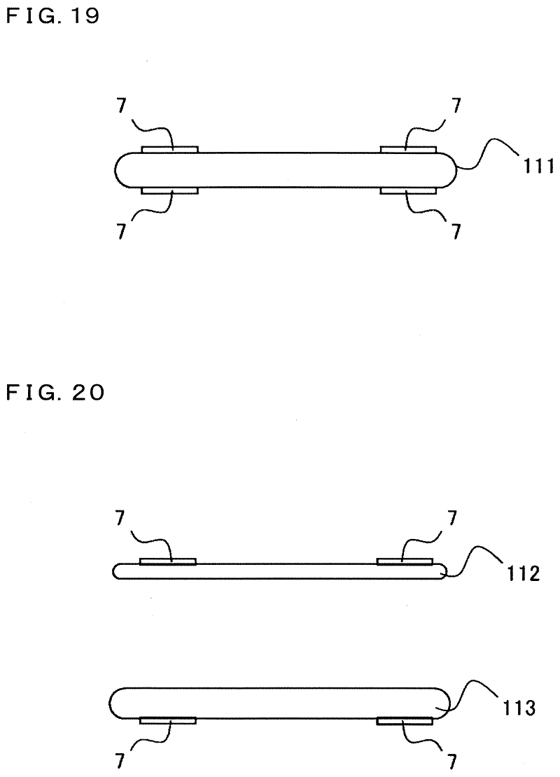

A semiconductor wafer 105 according to an embodiment 5 is described using FIG. 19 to FIG. 22. The description of a configuration similar to that in the embodiment 1 is omitted. In FIG. 19 to FIG. 22, the same reference numerals as those in FIG. 1 to FIG. 18 indicate the same or corresponding part. A method of manufacturing the semiconductor wafer 105 according to the present embodiment is different from that of manufacturing the semiconductor wafer 101 according to the embodiment 1. Points different from those in the embodiment 1 are mainly described hereinafter.

FIG. 19 to FIG. 22 are diagrams each illustrating the method of manufacturing the semiconductor wafer 105 according to the embodiment 5. FIG. 19 to FIG. 22 are diagrams each illustrating a cross section passing the center of the semiconductor wafer. The method of manufacturing the semiconductor wafer 105 according to the present embodiment is described. Firstly, as illustrated in FIG. 19, a light shielding part 7 is provided to an upper surface and a lower surface of a semiconductor wafer 111. The light shielding part 3, the light shielding part 4, or the light shielding part 5 described in the embodiment 1 to embodiment 3 can be applied to the light shielding part 7.

Next, the semiconductor chip is formed in the upper surface of the semiconductor wafer 111. Next, as illustrated in FIG. 20, the semiconductor wafer 111 in which the light shielding part 7 is provided to the upper surface and the lower surface is divided into two pieces. The semiconductor wafer 111 is divided in a direction parallel to the upper surface of the semiconductor wafer 111. The semiconductor wafer 111 is divided into an upper surface wafer 112 and a division wafer 113. The semiconductor chip is formed in the upper surface wafer 112. The semiconductor chip is not formed in the division wafer 113. Also in the other semiconductor wafer, the light shielding part is provided to the upper surface and the lower surface, and is divided into two pieces, and the other division wafer 114 in which the semiconductor chip is not formed is formed.

Next, a position of a notch part of the division wafer 113 is detected. The detection method described in the embodiment 1 can be used for detecting the notch part. A notch part of the other division wafer 114 formed by dividing the other semiconductor wafer is detected. The detection method described in the embodiment 1 can also be used for detecting the other notch part of the other division wafer 114.

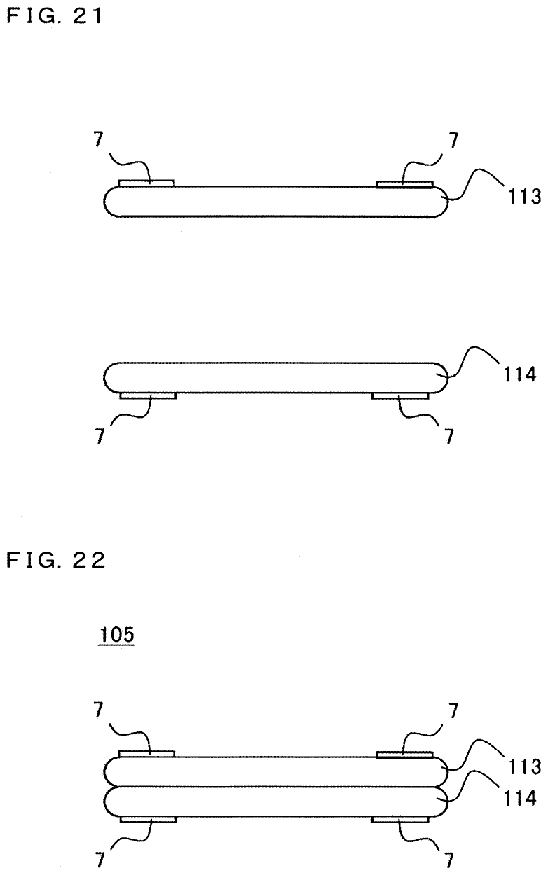

Next, as illustrated in FIG. 21, the division wafer 113 and the other division wafer 114 are disposed so that the detected notch part of the division wafer 113 and the detected other division wafer are overlapped with each other. Next, as illustrated in FIG. 22, the division wafer 113 and the other division wafer 114 are bonded to form the semiconductor wafer 105 as a regeneration wafer.

The method of manufacturing the semiconductor wafer 105 according to the present embodiment includes: the process of forming the light shielding part 7 in in the upper surface and the lower surface of the semiconductor wafer 111; the process of dividing the semiconductor wafer 111 into two pieces in the direction parallel to the upper surface of the semiconductor wafer 111 and forming the divided division wafer 113; the process of detecting the notch part 2 of the division wafer 113; the process of detecting the other notch part of the other division wafer 114 divided from the other semiconductor wafer; the process of locating the division wafer 113 and the other division wafer 114 so that the detected notch part 2 and the detected other notch part are overlapped with each other; and bonding the division wafer 113 and the other division wafer 114. Accordingly, the position of the notch part can be accurately detected in forming the regeneration wafer, and the positions of the division wafer 113 and the other division wafer 114 can be accurately aligned.

While the embodiments etc. have been described in detail, the above embodiments are not restrictive. Various modifications and replacements can be added to the above embodiments without departing from the scope of claims.

In the above embodiments described in the present specification, material properties, materials, dimensions, shapes, relative arrangement relations, or conditions for implementation, for example, for the respective constituent elements may be described; however, these represent an exemplification in all aspects, and are not limited to the above description. Accordingly, it is understood that numerous unexemplified modification examples can be devised within the scope of each embodiment. For example, involved are a case where an optional constituent element is modified, added, or omitted and further, a case where at least one of the constituent elements of at least one of the embodiments is extracted and then combined with constituent elements of the other embodiment.

The aspects of the present disclosure are collectively described hereinafter as appendixes.

### Appendix 1

At least one semiconductor wafer in which a semiconductor chip is formed, including:
at least one notch part provided to an edge part of the semiconductor wafer; and
a light shielding part provided to the edge part of a surface parallel to a surface in which the semiconductor chip is formed in surfaces included in the semiconductor wafer to sandwich an outer surrounding of the notch part or the notch part and having light transmissivity different from the surface in which the semiconductor chip is formed.

### Appendix 2

The semiconductor wafer according to Appendix 1, wherein
the light shielding part is provided to a whole periphery of the edge part of the semiconductor wafer.

### Appendix 3

The semiconductor wafer according to Appendix 1 or 2, wherein the light shielding part is a dot mark formed on an upper surface of the semiconductor wafer.

### Appendix 4

The semiconductor wafer according to Appendix 1, wherein the light shielding part is a griding mark with unevenness.

### Appendix 5

The semiconductor wafer according to Appendix 1, wherein
the light shielding part is a light shielding film including an inclined part.

### Appendix 6

The semiconductor wafer according to Appendix 1, wherein
the two semiconductor wafers are provided, and
the light shielding part is provided between the two semiconductor wafers attached to each other, and is an adhesive member having light transmissivity different from the semiconductor wafer.

### Appendix 7

The semiconductor wafer according to Appendix 6, wherein
the adhesive member is provided to the edge part of the semiconductor wafer.

### Appendix 8

The semiconductor wafer according to Appendix 6, wherein
the adhesive member is provided to a whole surface of the semiconductor wafer.

### Appendix 9

A method of manufacturing a semiconductor wafer in which a semiconductor chip is formed, comprising
forming a light shielding part in an edge part of a surface parallel to a surface in which the semiconductor chip is formed in surfaces included in the semiconductor wafer to sandwich an outer surrounding of a notch part provided to the edge part of the semiconductor wafer or the notch part and having light transmissivity different from the semiconductor wafer.

### Appendix 10

A method of manufacturing at least one semiconductor wafer in which a semiconductor chip is formed, comprising
locating an adhesive member having light transmissivity different from the semiconductor wafer between the two semiconductor wafers and attaching the two semiconductor wafers to each other by the adhesive member.

### Appendix 11

The method of manufacturing the semiconductor wafer according to Appendix 10, wherein
in attaching the two semiconductor wafers to each other by the adhesive member, edge parts of the two semiconductor wafers are attached to each other by the adhesive member.

### Appendix 12

The method of manufacturing the semiconductor wafer according to Appendix 10, wherein
in attaching the two semiconductor wafers to each other by the adhesive member, whole surfaces of the two semiconductor wafers are attached to each other by the adhesive member.

### Appendix 13

A method of manufacturing at least one semiconductor wafer, comprising:
detecting the notch parts of the semiconductor wafers according to any one of Appendixes 1 to 5;
locating the two semiconductor wafers so that the notch parts which have been detected are overlapped with each other;
locating an adhesive member having light transmissivity different from the semiconductor wafer between the two semiconductor wafers; and
attaching the two semiconductor wafers to each other by the adhesive member.

### Appendix 14

The method of manufacturing the semiconductor wafer according to Appendix 9, comprising:
forming the light shielding part in an upper surface and a lower surface of the semiconductor wafer;
dividing the semiconductor wafer into two pieces in a direction parallel to the upper surface of the semiconductor wafer and forming a divided division wafer;
detecting the notch part of the division wafer;
detecting another notch part of another division wafer divided from another semiconductor wafer;
locating the division wafer and the another division wafer so that the notched part which has been detected and the another notch part which has been detected are overlapped with each other; and
bonding the division wafer and the another division wafer.

While the disclosure has been shown and described in detail, the foregoing description is in all aspects illustrative and not restrictive. It is therefore understood that numerous modifications and variations can be devised.

What is claimed is:

1. At least one semiconductor wafer in which a semiconductor chip is formed, comprising:
at least one notch part provided to an edge part of the semiconductor wafer; and
a light shielding part provided to the edge part of a surface parallel to a surface in which the semiconductor chip is formed in surfaces included in the semiconductor wafer to sandwich an outer surrounding of the notch part or the notch part and having light transmissivity different from the surface in which the semiconductor chip is formed.

2. The semiconductor wafer according to claim 1, wherein
the light shielding part is provided to a whole periphery of the edge part of the semiconductor wafer.

3. The semiconductor wafer according to claim 1, wherein
the light shielding part is a dot mark formed on an upper surface of the semiconductor wafer.

4. The semiconductor wafer according to claim 1, wherein
the light shielding part is a griding mark with unevenness.

5. The semiconductor wafer according to claim 1, wherein
the light shielding part is a light shielding film including an inclined part.

6. The semiconductor wafer according to claim 1, wherein
the two semiconductor wafers are provided, and
the light shielding part is provided between the two semiconductor wafers attached to each other, and is an adhesive member having light transmissivity different from the semiconductor wafer.

7. The semiconductor wafer according to claim 6, wherein
the adhesive member is provided to the edge part of the semiconductor wafer.

8. The semiconductor wafer according to claim 6, wherein
the adhesive member is provided to a whole surface of the semiconductor wafer.

9. A method of manufacturing a semiconductor wafer in which a semiconductor chip is formed, comprising
forming a light shielding part in an edge part of a surface parallel to a surface in which the semiconductor chip is formed in surfaces included in the semiconductor wafer to sandwich an outer surrounding of a notch part provided to the edge part of the semiconductor wafer or the notch part and having light transmissivity different from the semiconductor wafer.

10. A method of manufacturing at least one semiconductor wafer in which a semiconductor chip is formed, comprising
locating an adhesive member having light transmissivity different from the semiconductor wafer between the two semiconductor wafers and attaching the two semiconductor wafers to each other by the adhesive member.

11. The method of manufacturing the semiconductor wafer according to claim 10, wherein
in attaching the two semiconductor wafers to each other by the adhesive member, edge parts of the two semiconductor wafers are attached to each other by the adhesive member.

12. The method of manufacturing the semiconductor wafer according to claim 10, wherein
in attaching the two semiconductor wafers to each other by the adhesive member, whole surfaces of the two semiconductor wafers are attached to each other by the adhesive member.

13. A method of manufacturing at least one semiconductor wafer, comprising:
detecting the notch parts of the semiconductor wafers according to claim 1;
locating the two semiconductor wafers so that the notch parts which have been detected are overlapped with each other;
locating an adhesive member having light transmissivity different from the semiconductor wafer between the two semiconductor wafers; and
attaching the two semiconductor wafers to each other by the adhesive member.

14. The method of manufacturing the semiconductor wafer according to claim 9, comprising:
forming the light shielding part in an upper surface and a lower surface of the semiconductor wafer;
dividing the semiconductor wafer into two pieces in a direction parallel to the upper surface of the semiconductor wafer and forming a divided division wafer;
detecting the notch part of the division wafer;
detecting another notch part of another division wafer divided from another semiconductor wafer;
locating the division wafer and the another division wafer so that the notched part which has been detected and the another notch part which has been detected are overlapped with each other; and
bonding the division wafer and the another division wafer.
